(19) United States
(12) Patent Application Publication
(10) Pub. No.: US 2002/0163370 A1
(43) Pub. Date: Nov. 7, 2002

(54) Operating method for a data bus

(76) Inventors: Martin Peller, Muenchen (DE); Josef Berwanger, Poing (DE)

Correspondence Address: CROWELL & MORING LLP, INTELLECTUAL PROPERTY GROUP, P.O. BOX 14300, WASHINGTON, DC, 20044-4300, US

(21) Appl. No.: 10/114,331

(22) Filed: Apr. 3, 2002

Related U.S. Application Data
(63) Continuation of application No. PCT/EP00/08785, filed on Sep. 8, 2000.

(30) Foreign Application Priority Data
Oct. 4, 1999 (DE) 199 47 662.4

(51) Int. Cl. H03L 7/00

(52) U.S. Cl. 327/144

(57) ABSTRACT

The invention relates to an operating method for a data bus which is provided with a clock generator. A second clock generator is activated when said first clock generator has a failure.

### CROSS-REFERENCE TO RELATED APPLICATIONS

This application is a continuation of PCT Application No. PCT/EP00/08785 filed Sep. 8, 2000.

This application is related to copending applications entitled “Data Bus for Several Users”, U.S. Ser. No. ______; “Operating Method for a Data Bus for Several Users With Flexible Timed Access”, U.S. Ser. No. ______; and “Operating Method for Two Data Buses”, U.S. Ser. No. ______, filed on even date herewith.

### BACKGROUND AND SUMMARY OF THE INVENTION

The invention relates to an operating method for a data bus having a clock pulse generator.

A data bus which can be used within the scope of the invention is disclosed in German Patent document DE 19720401 A. The data bus described therein preferably has a star-type topology. However, it may also have a bus topology known per se in which the users communicate with one another by way of one or several data lines. The data bus contains a bus master which generates synchronization pulses so that the communication can take place between the users.

When this bus master fails, a communication is no longer possible. It is therefore conceivable to define a user as an equivalent master which generates synchronization pulses when the bus master fails. This is detected by the equivalent master because of the fact that there are no synchronization pulses. However, if, for example, the reception line of the equivalent master is defective, but its transmission line is still operable, the equivalent master would erroneously activate and thereby interfere with the data traffic because it would generate synchronization pulses in a fashion unsynchronized with the actual bus master.

It is an object of the invention to provide an operating method for a data bus of the initially mentioned type by means of which the described problem of an erroneous activation of an equivalent master can be avoided.

This, and other objects are achieved according to the invention by an operating method for a data bus having a clock pulse generator. The method is characterized in that when the clock pulse generator fails, a second clock pulse generator is activated.

In one embodiment, in a normal case, the first and the second clock pulse generator are activated simultaneously and are mutually synchronized. Advantageously, the clock pulse generator with the higher frequency synchronizes the clock pulse generator with a lower frequency to its clock pulse frequency. Further advantageously, the clock pulse generator with the lower frequency stops its transmission operation.

In another embodiment of the invention, a clock pulse generator having a lower frequency will be synchronized with a clock pulse generator having a higher frequency only when the clock pulse frequency of the latter does not exceed a defined rate.

### BRIEF DESCRIPTION OF THE DRAWING

FIG. 1 is a flow chart illustrating an operating method for a data bus according to the present invention.

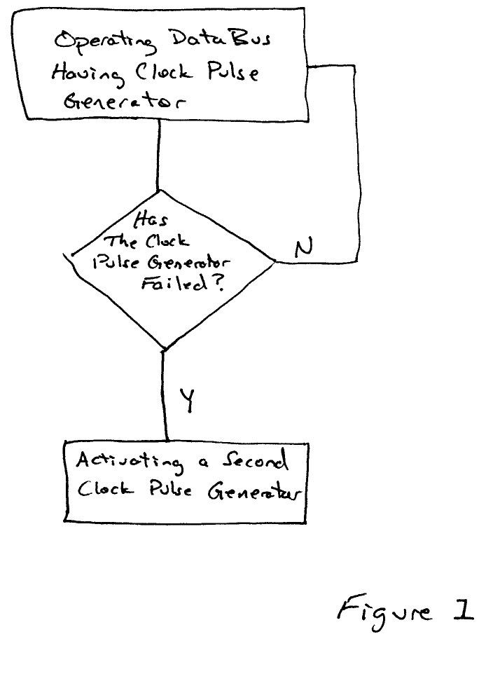

### DETAILED DESCRIPTION OF THE DRAWING

Referring to the figure, the problem of the prior art is solved by the targeted and intentional activation of several bus masters on the data bus. The different bus masters synchronize one another such that, for example, the bus master with the “fastest clock” (clock pulse generator with the highest frequency) always prevails with its synchronization sequence and synchronizes all other bus masters.

In order to avoid a bus master from placing a synchronization sequence completely outside the synchronization window (defined by the crystal inaccuracies), an independent monitoring element can, for example, be used. The independent monitoring element releases the bus access only in the permitted synchronization window. If a bus access of a bus master erroneously takes place, the monitoring device can block the access, and inform the data bus system or the users in an appropriate manner of the error (for example, by way of a serial interface to the microprocessor of the bus master and from there, all users by “alive counter”), so that corresponding measures can be taken at the system level. These measures may, for example, consist of bringing a control system, depending on the data bus system, into a secure condition.

In the case of a data bus constructed as a star-type coupler, advantageous embodiments of the invention consist of the fact that the clock pulse generator itself is arranged in a star-type coupler and/or, when a protocol controller is present, that the clock pulse generator is integrated in the protocol controller.

The problem of the erroneous activation of the equivalent master can therefore be solved in this manner.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. An operating method for a data bus having a first clock pulse generator, the method comprising the acts of:
determining a failure of the first clock pulse generator; and
activating a second clock pulse generator when the first clock pulse generator fails.

2. The operating method according to claim 1, wherein, under normal operating conditions, the first and the second clock pulse generator are activated simultaneously and are mutually synchronized.

3. The operating method according to claim 2, further comprising the acts of:
synchronizing one of the first and second clock pulse generators having a lower frequency to a clock pulse frequency of the other one of the first and second clock pulse generators having a higher frequency.

4. The operating method according to claim 3, further comprising the act of stopping a transmission operation of the clock pulse generator having the lower frequency.

5. The operating method according to claim 2, wherein a clock pulse generator having a lower frequency is synchronized with a clock pulse generator having a higher frequency only when a clock pulse frequency of the clock pulse generator having a higher frequency does not exceed a defined rate.

6. The operating method according to claim 3, wherein a clock pulse generator having a lower frequency is synchronized with a clock pulse generator having a higher frequency only when a clock pulse frequency of the clock pulse generator having a higher frequency does not exceed a defined rate.

7. The operating method according to claim 4, wherein a clock pulse generator having a lower frequency is synchronized with a clock pulse generator having a higher frequency only when a clock pulse frequency of the clock pulse generator having a higher frequency does not exceed a defined rate.
